(19) United States
(12) Patent Application Publication
(10) Pub. No.: US 2026/0059737 A1
(43) Pub. Date: Feb. 26, 2026

(54) SEMICONDUCTOR DEVICE AND METHOD OF MANUFACTURING THE SAME

(71) Applicant: SAMSUNG ELECTRONICS CO., LTD., Suwon-si (KR)

(72) Inventor: Changhyuck Sung, Suwon-si (KR)

(73) Assignee: SAMSUNG ELECTRONICS CO., LTD., Suwon-si (KR)

(21) Appl. No.: 19/234,878

(22) Filed: Jun. 11, 2025

(30) Foreign Application Priority Data
Aug. 20, 2024 (KR) 10-2024-0111629

(51) Int. Cl. H10B 12/00

(52) U.S. Cl. CPC H10B 12/30; H10B 12/03; H10B 12/05

(57) ABSTRACT

A semiconductor device may include: a bit line extending in a vertical direction; a word line extending in a horizontal direction; a channel region around the word line; a gate insulating layer between the word line and the channel region; a capacitor including: an internal electrode connected to the channel region; a dielectric film around the internal electrode; and an external electrode around the internal electrode with the dielectric film therebetween; and an intermediate oxide layer between the bit line and the channel region.

### CROSS-REFERENCE TO RELATED APPLICATION

This application is based on and claims priority under 35 U.S.C. § 119 to Korean Patent Application No. 10-2024-0111629, filed on Aug. 20, 2024, in the Korean Intellectual Property Office, the disclosure of which is incorporated by reference herein in its entirety.

### BACKGROUND

### 1. Field

The disclosure relates to a semiconductor device and a method of manufacturing the same. Specifically, the disclosure relates to a semiconductor device including a plurality of memory cells arranged three-dimensionally and a method of manufacturing the semiconductor device.

### 2. Description of Related Art

Due to advances in electronics technology, the down-scaling of semiconductor devices has been very rapid recently. Accordingly, miniaturization of memory cells is desired, and there are limits to improving the integration and maintaining reliability in existing memory cells.

### SUMMARY

Therefore, it is desired to develop a semiconductor device having a structure that facilitates miniaturization and high integration of memory cells.

One or more embodiments of the disclosure provide a semiconductor device having improved electrical characteristics and a method of manufacturing the semiconductor device.

According to one or more example embodiments, a semiconductor device may include: a bit line extending in a vertical direction; a word line extending in a horizontal direction; a channel region around the word line; a gate insulating layer between the word line and the channel region; a capacitor including: an internal electrode connected to the channel region; a dielectric film around the internal electrode; and an external electrode around the internal electrode with the dielectric film therebetween; and an intermediate oxide layer between the bit line and the channel region.

According to one or more example embodiments, a semiconductor device may include: a bit line including a first portion extending in a vertical direction and a second portion protruding from the first portion in a first horizontal direction; a word line extending in a second horizontal direction intersecting the first horizontal direction; a channel region around at least a part of the word line; a gate insulating layer between the word line and the channel region; a capacitor including: an internal electrode connected to the channel region; a dielectric film around the internal electrode; and an external electrode around the internal electrode with the dielectric film therebetween; and an intermediate oxide layer between the second portion and the channel region.

According to one or more example embodiments, a semiconductor device may include: a bit line extending in a vertical direction; interlayer insulating layers; word lines alternately stacked with the interlayer insulating layers and extending in a horizontal direction; insulating patterns between the word lines and the bit line; channel regions around the insulating patterns and the word lines; gate insulating layers between the word lines and the channel regions and between the insulating patterns and the channel regions; a capacitor including: internal electrodes connected to the channel regions; dielectric films around the internal electrodes; and external electrodes around the internal electrodes with the dielectric films therebetween; and an intermediate oxide layer between the bit line and the channel regions and extending in the vertical direction along a sidewall of the bit line.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor device according to one or more embodiments;

FIG. 2 is an enlarged cross-sectional view of a portion EX1 of FIG. 1 according to one or more embodiments;

FIG. 3 is a cross-sectional view of a semiconductor device, according to one or more embodiments;

FIG. 4 is an enlarged cross-sectional view of a portion EX2 of FIG. 3;

FIG. 5 is a cross-section view for describing a method of manufacturing a semiconductor device according to one or more embodiments;

FIG. 6 is a cross-section view for describing a method of manufacturing a semiconductor device according to one or more embodiments;

FIG. 7 is a cross-section view for describing a method of manufacturing a semiconductor device according to one or more embodiments;

FIG. 8 is a cross-section view for describing a method of manufacturing a semiconductor device according to one or more embodiments;

FIG. 9 is a cross-section view for describing a method of manufacturing a semiconductor device according to one or more embodiments;

FIG. 10 is a cross-section view for describing a method of manufacturing a semiconductor device according to one or more embodiments;

FIG. 11 is a cross-section view for describing a method of manufacturing a semiconductor device according to one or more embodiments;

FIG. 12 is a cross-section view for describing a method of manufacturing a semiconductor device according to one or more embodiments;

FIG. 13 is a cross-section view for describing a method of manufacturing a semiconductor device according to one or more embodiments;

FIG. 14 is a cross-section view for describing a method of manufacturing a semiconductor device according to one or more embodiments;

FIG. 15 is a cross-section view for describing a method of manufacturing a semiconductor device according to one or more embodiments;

FIG. 16 is a cross-section view for describing a method of manufacturing a semiconductor device according to one or more embodiments;

FIG. 17 is a cross-section view for describing a method of manufacturing a semiconductor device according to one or more embodiments;

FIG. 18 is a cross-sectional view for describing a method of manufacturing a semiconductor device according to one or more embodiments; and

FIG. 19 is a cross-sectional view for describing a method of manufacturing a semiconductor device according to one or more embodiments.

### DETAILED DESCRIPTION

Hereinafter, various embodiments will be described in detail with reference to the accompanying drawings. Like components in the drawings will be referred to as like reference numerals, and will not be repeatedly described.

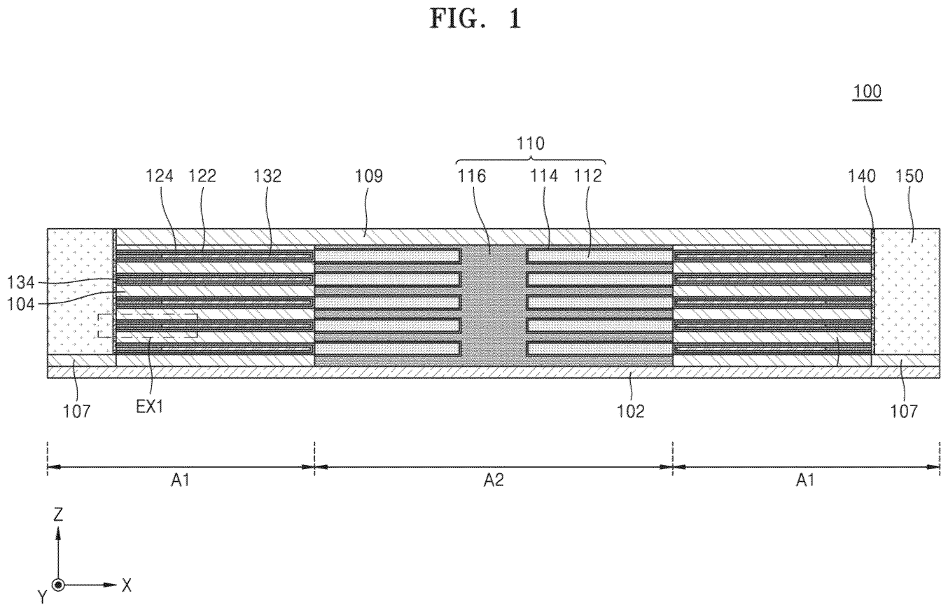

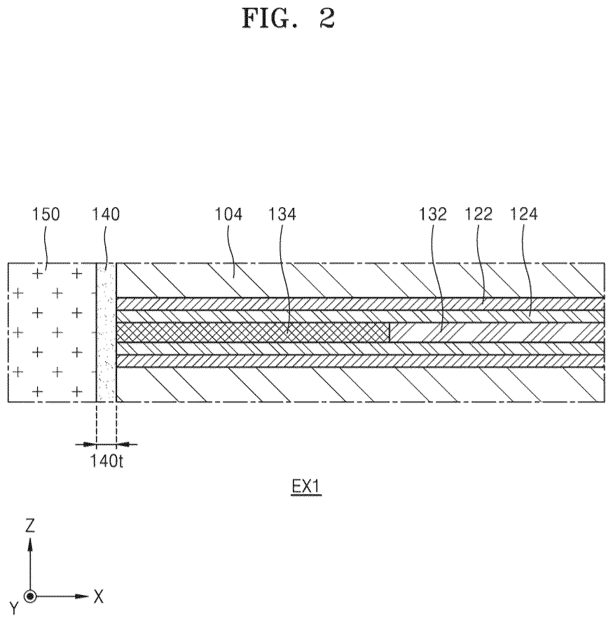

FIG. 1 is a cross-sectional view of a semiconductor device 100 according to one or more embodiments. FIG. 2 is an enlarged cross-sectional view of a portion EX1 of FIG. 1.

Referring to FIGS. 1 and 2, the semiconductor device 100 may include a substrate 102, a capacitor 110, a plurality of channel regions 122, a plurality of word lines 132, and a plurality of bit lines 150.

The substrate 102 may include a semiconductor element such as Ge or a compound semiconductor such as SiC, GaAs, InAs, and InP. The substrate 102 may include a semiconductor substrate, at least one insulating film formed on the semiconductor substrate, or structures including at least one conductive region. The conductive region may include, for example, an impurity-doped well or an impurity-doped structure. In one or more embodiments, the substrate 102 may have various device isolation structures such as a shallow trench isolation (STI) structure.

A plurality of capacitors 110 may be located in a second region A2 of the substrate 102. Hereinbelow, for convenience of a description, a region on the substrate 102 where the plurality of capacitors 110 are arranged will be referred to as the second region A2, and a region on the substrate 102 where the plurality of bit lines 150 and the plurality of word lines 132 are arranged will be referred to as a first region A1. The plurality of capacitors 110 each may include internal electrodes 112, external electrodes 116 surrounding the internal electrodes 112, and dielectric films 114 arranged between the internal electrodes 112 and the external electrodes 116.

The internal electrodes 112 may be arranged spaced apart from each other in a vertical direction (a Z direction). The internal electrode 112 may contact the channel region 122 on a side. The capacitor 110 may be connected to the channel region 122 through the internal electrode 112. Surfaces of the internal electrode 112 may be surrounded by the dielectric film 114. The external electrode 116 may surround the internal electrode 112 with the dielectric film 114 therebetween.

In one or more embodiments, each of the internal electrode 112 and the external electrode 116 may include Ti, a Ti nitride, a Ti oxide, a Ti oxynitride, Nb, an Nb nitride, an Nb oxide, an Nb oxynitride, Co, a Co nitride, a Co oxide, a Co oxynitride, Sn, an Sn nitride, an Sn oxide, an Sn oxynitride, or a combination thereof. For example, each of the internal electrode 112 and the external electrode 116 may include TiN, NbN, CoN, SnO₂, or a combination thereof. In one or more embodiments, each of the internal electrode 112 and the external electrode 116 may include TaN, TiAlN, TaAlN, V, VN, Mo, MoN, W, WN, Ru, RuO₂, SrRuO₃, Ir, IrO₂, Pt, PtO, SRO(SrRuO₃), BSRO((Ba,Sr)RuO₃), CRO(CaRuO₃), LSCO((La,Sr)CoO₃), or a combination thereof. However, the disclosure is not limited thereto.

In one or more embodiments, the dielectric film 114 may include a silicon oxide film, a high dielectric film, or a combination thereof. In one or more embodiments, the dielectric film 114 may include metal oxide containing at least one metal selected from Hf, Zr, Al, Nb, Ce, La, Ta, and Ti. In one or more embodiments, the dielectric film 114 may have a single-film structure including one high-k dielectric film. In one or more embodiments, the dielectric film 114 may have a multi-film structure including a plurality of dielectric films sequentially stacked on the internal electrode 112. The high-k dielectric film may be selected from, but not limited to, an HfO₂ film, a ZrO₂ film, an Al₂O₃ film, an La₂O₃ film, a Ta₂O₃ film, an Nb₂O₅ film, a CeO₂ film, a TiO₂ film, and a GeO₂ film. In one or more embodiments, the dielectric film 114 may include an oxide of at least one metal selected from among Ti, Nb, Ta, Sn, and Mo or an oxynitride of at least one metal selected from among Ti, Nb, Ta, Sn, and Mo. For example, the dielectric film 114 may include a Ti oxide, a Ti oxynitride, an Nb oxide, an Nb oxynitride, a Ta oxide, a Ta oxynitride, an Sn oxide, an Sn oxynitride, an Mo oxide, an Mo oxynitride, or a combination thereof. In one or more embodiments, the dielectric film 114 may include a ferroelectric film including at least one oxide selected from among Hf, Si, Al, Zr, Y, La, Gd and Sr. The ferroelectric film may include hafnium-based oxides, such as a hafnium oxide (HfO), a hafnium zirconium oxide (HZO), a hafnium titanium oxide, or a hafnium silicon oxide. The ferroelectric film may further include a dopant depending on a need. The dopant may include, but not limited to, at least one element selected from Si, Al, Zr, Y, La, Gd, Sc, Sr, Mg, and Ba.

Each of the plurality of word lines 132 may have a form of a line or a bar extending in a second horizontal direction (a Y direction). The plurality of word lines 132 may be stacked spaced apart from each other in the vertical direction (the Z direction). Each of the plurality of word lines 132 may include a conductive material. The conductive material may include, for example, any one of doped semiconductor materials (doped silicon, doped germanium, etc.), conductive metal nitrides (a titanium nitride, a tantalum nitride, etc.), metals (tungsten, titanium, tantalum, etc.), and metal-semiconductor compounds (a tungsten silicide, a cobalt silicide, a titanium silicide, etc.).

An insulating pattern 134 may be arranged between the plurality of word lines 132 and the plurality of bit lines 150. The insulating pattern 134 may have the same vertical length as the word line 132. The insulating pattern 134 may include, for example, a nitride. The nitride may include, for example, a silicon nitride.

The plurality of channel regions 122 may extend in a first horizontal direction (an X direction) while surrounding the plurality of word lines 132 and the insulating pattern 134. The plurality of channel regions 122 may be stacked spaced apart from each other in the vertical direction (the Z direction). The channel region 122 may contact the internal electrode 112 of the capacitor 110 in one end portion thereof and may contact an intermediate oxide layer 140 in the other end portion thereof.

The channel region 122 may include silicon (Si), for example, single crystal silicon, polycrystalline silicon, or amorphous silicon. In one or more embodiments, the channel region 122 may include at least one selected from among Ge, SiGe, SiC, GaAs, InAs, and InP. In one or more embodiments, the channel region 122 may include an oxide semiconductor material. An oxide semiconductor material forming the channel region 122 may include, but not limited to, at least one selected from among InGaZnO (IGZO), Sn—IGZO, InWO (IWO), InZnO (IZO), ZnSnO (ZTO), ZnO, ZnON, a yttrium-doped zinc oxide (YZO), InGaSiO, InO, SnO, TiO, ZnON, MgZnO, InZnO, ZrInZnO, HfInZnO, SnInZnO, AlSnInZnO, SiInZnO, AlZnSnO, GaZnSnO, and ZrZnSnO. For example, the oxide semiconductor material forming the channel region 122 may be IGZO. In one or more embodiments, the channel region 122 may further include at least one dopant selected from among aluminum (Al), boron (B), arsenic (As), fluorine (F), and hydrogen (H) as well as at least one oxide semiconductor material selected from among the oxide semiconductor materials listed above.

A gate insulating layer 124 may be arranged between the word line 132 and the channel region 122 and between the insulating pattern 134 and the channel region 122. The gate insulating layer 124 may include at least one selected between a high-k dielectric material having a higher dielectric constant than a silicon oxide and a ferroelectric material. In one or more embodiments, the gate insulating layer 124 may include at least one material selected from among a hafnium oxide (HfO), a hafnium silicate (HfSiO), a hafnium oxynitride (HfON), a hafnium silicon oxynitride (HfSiON), a lanthanum oxide (LaO), a lanthanum aluminum oxide (LaAlO), a zirconium oxide (ZrO), a zirconium silicate (ZrSiO), a zirconium oxynitride (ZrON), a zirconium silicon oxynitride (ZrSiON), a tantalum oxide (TaO), a titanium oxide (TiO), a barium strontium titanium oxide (BaSrTiO), a barium titanium oxide (BaTiO), a lead zirconate titanate (PZT), a strontium bismuth tantalate (STB), a bismuth iron oxide (BFO), a strontium titanium oxide (SrTiO), a yttrium oxide (YO), an aluminum oxide (AlO), or a lead scandium tantalum oxide (PbScTaO).

The word line 132, the gate insulating layer 124, and the channel region 122 may form a memory cell transistor together.

A plurality of interlayer insulating layers 104 may be arranged between the plurality of word lines 132. Each of the plurality of interlayer insulating layers 104 may space each of the plurality of word lines 132 apart from each other in the vertical direction (the Z direction). An upper insulating layer 109 may be arranged on the interlayer insulating layer 104 located on top. The upper insulating layer 109 may cover a top surface of the capacitor 110 and a top surface of the interlayer insulating layer 104 that is located on top. A side surface of the upper insulating layer 109 may contact the intermediate oxide layer 140. A lower insulating layer 107 may be arranged between the plurality of bit lines 150 and the substrate 102. Each of the interlayer insulating layer 104, the upper insulating layer 109, and the lower insulating layer 107 may include, for example, a silicon oxide. While it is shown in FIGS. 1 and 2 that the interlayer insulating layer 104, the upper insulating layer 109, and the lower insulating layer 107 are distinguished from one another, this illustration is intended for convenience of a description and the interlayer insulating layer 104, the upper insulating layer 109, and the lower insulating layer 107 may not be distinguished from one another and may form one piece.

The plurality of bit lines 150 may be arranged at an end of the first region A2 of the substrate 102 and may extend in the vertical direction (the Z direction). Each of the plurality of bit lines 150 may have a form of a line or a pillar extending in the vertical direction (the Z direction). The plurality of bit lines 150 may be respectively arranged spaced apart from one another in the second horizontal direction (the Y direction).

In one or more embodiments, the bit line 150 may include a conductive material. The conductive material may include, for example, any one of a doped semiconductor material, a conductive metal nitride, a metal, and a metal-semiconductor compound.

The intermediate oxide layer 140 may be arranged between the bit line 150 and the channel region 122. The intermediate oxide layer 140 may extend in the vertical direction (the Z direction) along a sidewall located inward relative to the other between opposite sidewalls of the bit line 150. The bit line 150 and the channel region 122 may be horizontally spaced apart from each other with the intermediate oxide layer 140 therebetween. The intermediate oxide layer 140 may contact the bit line 150 in a sidewall and contact the channel region 122, the interlayer insulating layer 104, the gate insulating layer 124, and the insulating pattern 134 in the other sidewall facing the sidewall in the first horizontal direction (the X direction). Meanwhile, at a vertical level in which the word line 132 is located, the insulating pattern 134 may be arranged between the word line 132 and the intermediate oxide layer 140.

In one or more embodiments, a top surface of the intermediate oxide layer 140 may be on the same plane as a top surface of the bit line 150, and a bottom surface of the intermediate oxide layer 140 may be the same plane as a bottom surface of the bit line 150.

In one or more embodiments, the intermediate oxide layer 140 may include a binary oxide. The binary oxide may include, but not limited to, for example, Al₂O₃, TiO₂, ZnO, or a combination thereof.

In one or more embodiments, a horizontal width 140t of the intermediate oxide layer 140 may be about 0.5 nm to about 3.0 nm. When the horizontal width 140t of the intermediate oxide layer 140 is less than the above-described range, a resistance reduction effect of the bit line 150 may not be achieved by the intermediate oxide layer 140, and when the horizontal width 140t of the intermediate oxide layer 140 is greater than the above-described range, the intermediate oxide layer 140 may be excessively thickened, increasing the resistance of the bit line 150.

The semiconductor device 100 according to one or more embodiments may include the intermediate oxide layer 140 that is arranged between the bit line 150 and the channel region 122 and includes a binary oxide. As the intermediate oxide layer 140 is arranged between the bit line 150 and the channel region 122, a metal induced gap state between the bit line 150 and the channel region 122 is reduced such that thus a contact resistance between the bit line 150 and the channel region 122 is reduced and operating characteristics of a memory cell transistor including the word line 132, the gate insulating layer 124, and the channel region 122 may be improved. Thus, the electrical characteristics of the semiconductor device 100 may be improved.

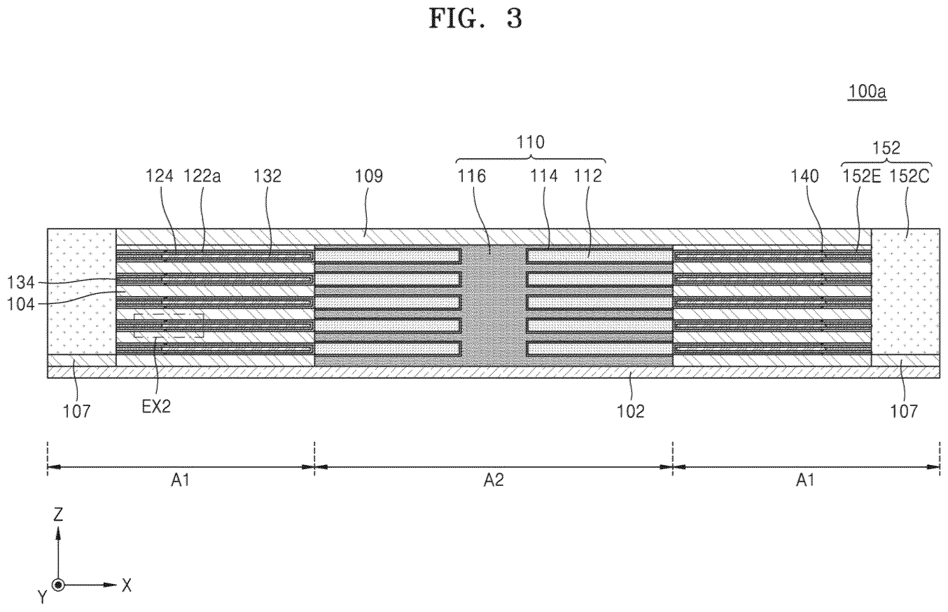

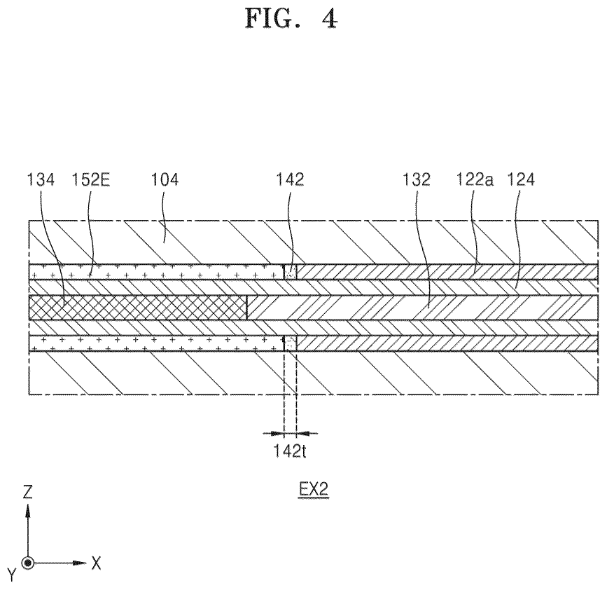

FIG. 3 is a cross-sectional view of a semiconductor device 100a according to one or more embodiments. FIG. 4 is an enlarged cross-sectional view of a portion EX2 of FIG. 3. Components of the semiconductor device 100a shown in FIGS. 3 and 4 are similar to the components of the semiconductor device 100 shown in FIGS. 1 and 2, and thus the following description will be focused on a difference therebetween.

Referring to FIGS. 3 and 4, the semiconductor device 100a may have a globally similar structure as the semiconductor device 100 shown in FIGS. 1 and 2 except that the semiconductor device 100a includes a bit line 152 including a first portion 152C and a second portion 152E and the intermediate oxide layer 142 arranged between the second portion 152E and a channel region 122a.

The semiconductor device 100a may include the bit line 152 including a first portion 152C and a plurality of second portions 152E protruding from the first portion 152C in the first horizontal direction (the X direction), the channel region 122a surrounding at least a part of the word line 132, and the intermediate oxide layer 142 arranged between the channel region 122a and the second portion 152E of the bit line 152.

The first portion 152C of the bit line 152 may be arranged in an end of the first region A2 of the substrate 10 and extend in the vertical direction (the Z direction). The first portion 152C may be arranged on the lower insulating layer 107. The second portion 152E of the bit line 152 may protrude in the first horizontal direction (the X direction) from a sidewall located inward relative to the other between both sidewalls of the first portion 152C. The plurality of second portions 152E may be spaced apart from each other in the vertical direction (the Z direction). The second portion 152E may be located at the same vertical level as the channel region 122a. The second portion 152E may overlap the insulating pattern 134 and a part of the word line 132 in the vertical direction (the Z direction). That is, the second portion 152E of the bit line 152 may further extend over the insulating pattern 134 toward the channel region 122a.

The intermediate oxide layer 142 may be arranged between the second portion 152E of the bit line 152 and the channel region 122a. The intermediate oxide layer 142 may overlap the word line 132 in the vertical direction (the Z direction). That is, the word line 132 may further extend over the channel region 122a toward the bit line 152. The channel region 122a may overlap the word line 132 in the vertical direction (the Z direction) and may not overlap the insulating pattern 134 in the vertical direction (the Z direction).

The top surface of the intermediate oxide layer 142 may be located the same plane as the top surface of the second portion 152E and the top surface of the channel region 122a, and the bottom surface of the intermediate oxide layer 142 may be located on the same plane as the bottom surface of the second portion 152E and the bottom surface of the channel region 122a. That is, the intermediate oxide layer 142, the second portion 152E of the bit line 152, and the channel region 122a may be located at the same vertical level.

In one or more embodiments, a horizontal width 142t of the intermediate oxide layer 142 may be about 0.5 nm to about 3.0 nm.

In one or more embodiments, the intermediate oxide layer 142 may include a binary oxide. The binary oxide may include, for example, Al₂O₃, TiO₂, ZnO, or a combination thereof.

The insulating pattern 134 may be arranged between the word line 132 and the first portion 152C of the bit line 152. The insulating pattern 134 may contact the word line 132 on a sidewall and may contact the first portion 152C on the other sidewall facing the sidewall in the first horizontal direction (the X direction). The insulating pattern 134 may overlap the second portion 152E of the bit line 152 in the vertical direction (the Z direction).

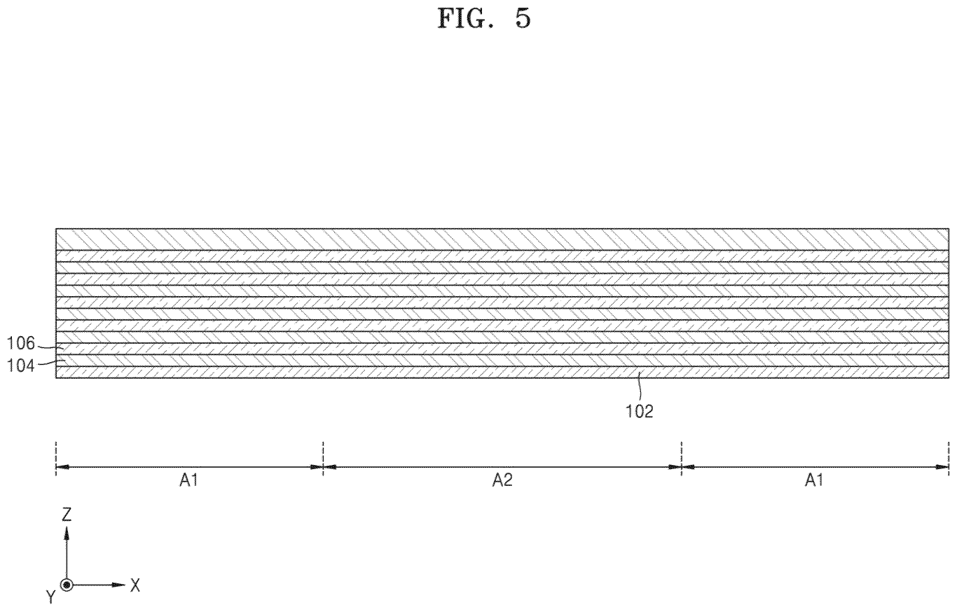

FIGS. 5 to 17 are cross-sectional views for describing a method of manufacturing the semiconductor device 100 according to one or more embodiments.

Referring to FIG. 5, the interlayer insulating layer 104 and a sacrificial layer 106 may be sequentially stacked on the substrate 102. The interlayer insulating layer 104 and the sacrificial layer 106 may be formed, for example, by a deposition process. The interlayer insulating layer 104 and the sacrificial layer 106 may be formed of materials having etch selectivities with respect to each other. For example, the interlayer insulating layer 104 may include, for example, a silicon oxide, and the sacrificial layer 106 may include a silicon nitride. The number of pairs of the interlayer insulating layer 104 and the sacrificial layer 106 stacked on the substrate 102 may correspond to the number of layers of a memory cell to be implemented on the substrate 102 and may be selected variously depending on a need.

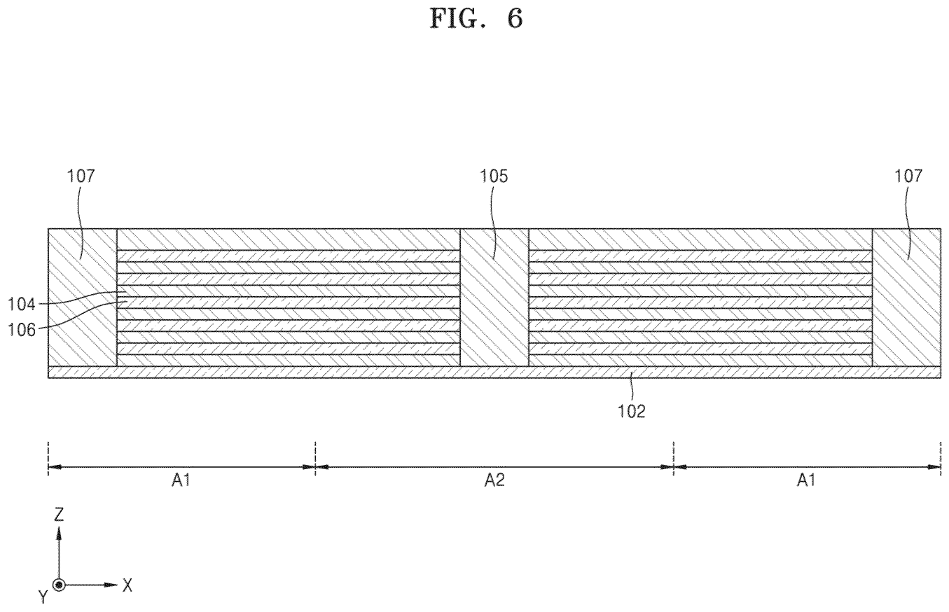

Referring to FIG. 6, in a resultant product of FIG. 5, by etching a part of each of a pair of first regions A1 and a part of the second region A2 arranged between the pair of first regions A1, a first vertical hole and a second vertical hole passing through the part of each of the pair of first regions A1 and the part of the second region A2 in the vertical direction (the Z direction) may be formed.

Next, an insulating layer 105 filling the first vertical hole and the lower insulating layer 107 filling the second vertical hole may be formed. The insulating layer 105 and the lower insulating layer 107 may be formed by, for example, a deposition process, and then may be planarized by a planarization process. The planarization process may be, for example, chemical mechanical polishing (CMP). Each of the insulating layer 105 and the lower insulating layer 107 may include, for example, a silicon oxide.

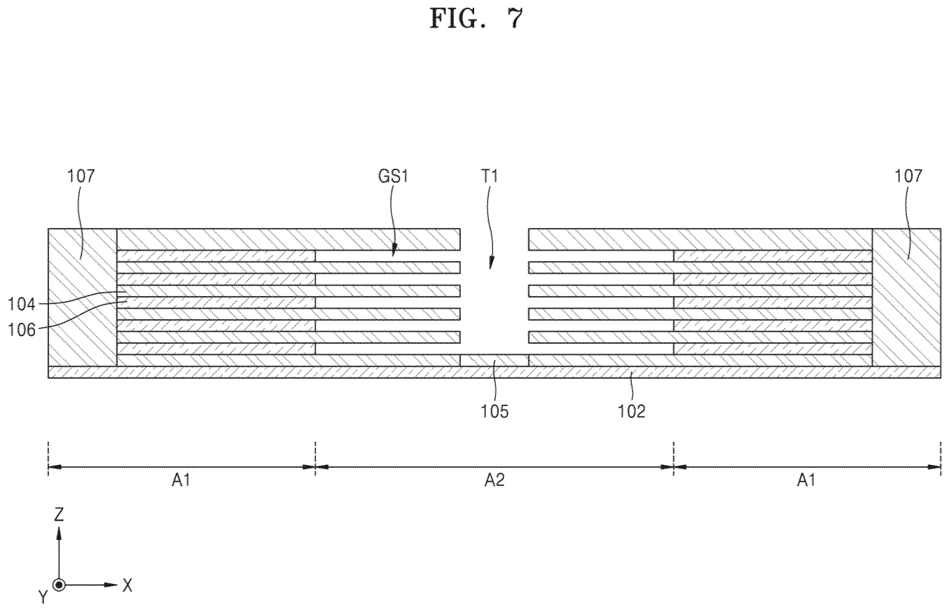

Referring to FIG. 7, in a resultant product of FIG. 6, a first trench T1 may be formed by removing a part of the insulating layer 105, and a first space GS1 may be formed by removing parts of the sacrificial layer 106 in the second region A2 through the first trench T1. The formed first trench T1 and the first space GS1 may communicate with each other. The first space GS1 may be formed by, for example, a wet etching process.

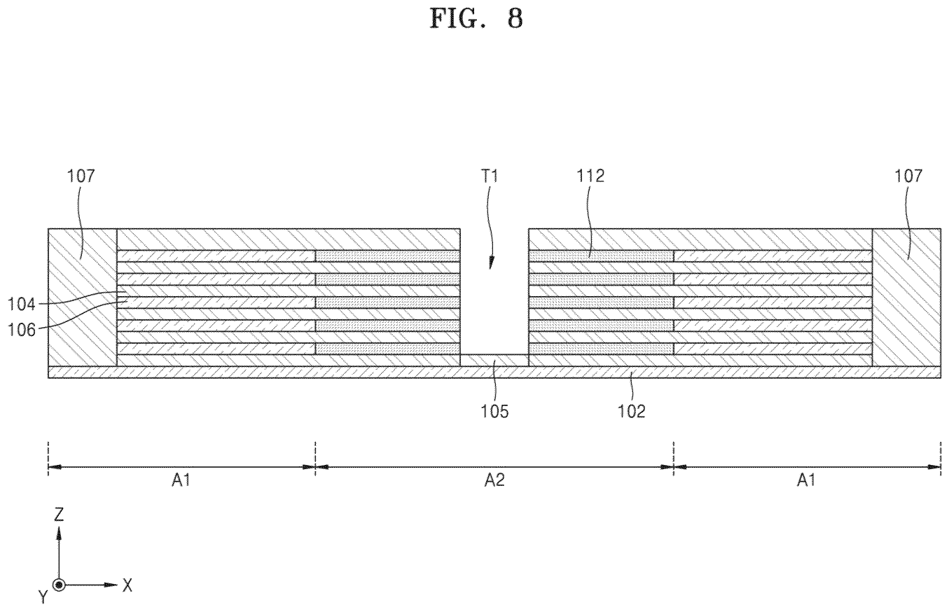

Referring to FIG. 8, in a resultant product of FIG. 7, after the first space GS1 (see FIG. 7) and the first trench T1 are filled with a conductive material, a part of the conductive material, which fills the first trench T1, may be removed, thereby forming the internal electrode 112 filling only the first space GS1 (see FIG. 7). The conductive material may include, for example, a metal film, a conductive metal oxide film, a conductive metal nitride film, a conductive metal oxynitride film, or a combination thereof.

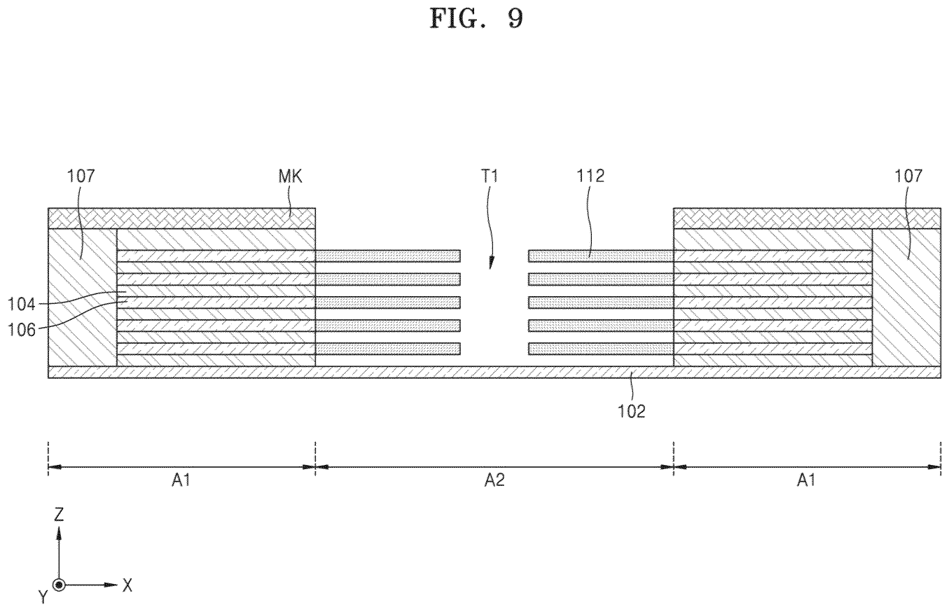

Referring to FIG. 9, in a resultant product of FIG. 8, a mask pattern MK exposing the second region A2 may be formed on the interlayer insulating layer 104 located on top. The mask pattern MK may include, for example, a photoresist material.

Next, by removing the insulating layer 105 (see FIG. 8) and a part of the interlayer insulating layer 104 in the second region A2 by using the mask pattern MK, a second space GS2 may be formed. The second space GS2 may communicate with the first trench T1. The second space GS2 may be formed by, for example, a wet etching process. A part of the internal electrode 112 and the top surface of the substrate 102 in the second region A2 may be exposed by the second space GS2.

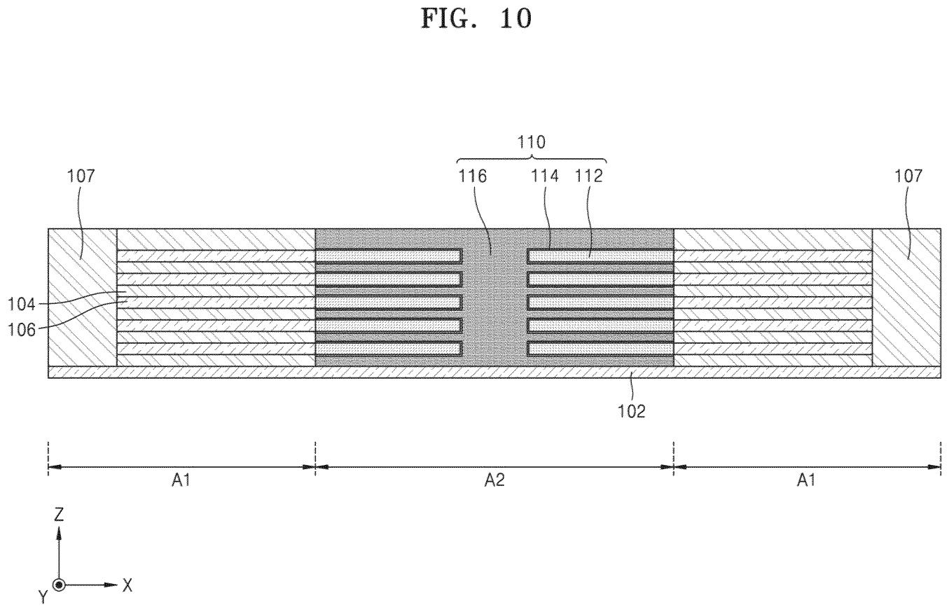

Referring to FIG. 10, in a resultant product of FIG. 9, the mask pattern MK (see FIG. 9) may be removed from the interlayer insulating layer 104 located on top.

Next, after the dielectric film 114 surrounding the surface of the internal electrode 112 is formed, the external electrode 116 surrounding the internal electrode 112 with the dielectric film 114 therebetween while filling the first trench T1 (see FIG. 9) and the second space GS2 (see FIG. 9) may be formed.

A material of the dielectric film 114 and a material of the external electrode 116 may be as described above in the description of the semiconductor device 100 shown in FIGS. 1 and 2.

The dielectric film 114 and the external electrode 116 may be formed, for example, by a deposition process.

In one or more embodiments, a plasma process may be performed on the internal electrode 112 after removing the mask pattern MK (see FIG. 9) before forming the dielectric film 114. A plasma gas used in the plasma process may be, for example, an NH₃ gas. In one or more embodiments, a processing temperature of the plasma process may be about 600° C.

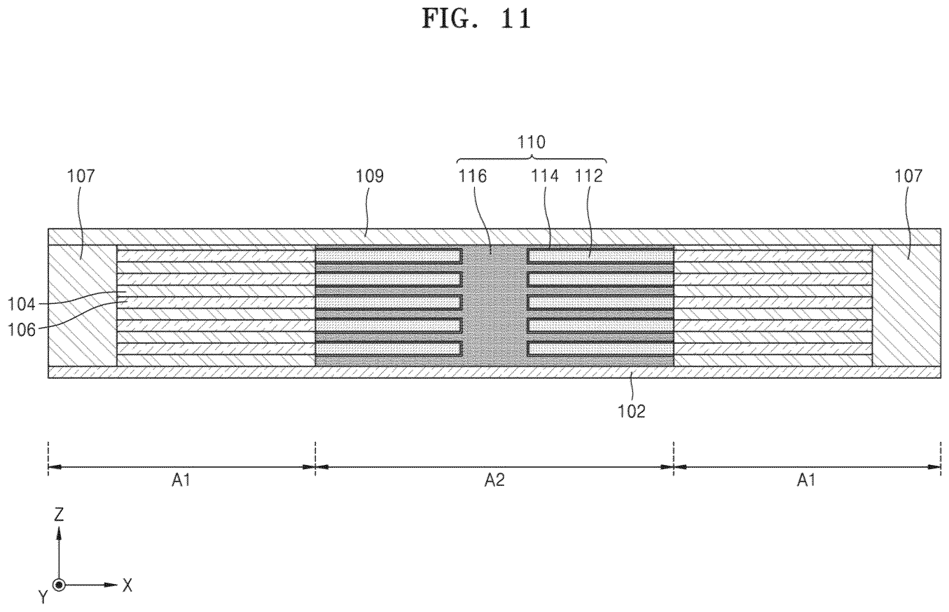

Referring to FIG. 11, in a resultant product of FIG. 10, by performing a planarization process, a top portion of the interlayer insulating layer 104 located on top and a top portion of the external electrode 116 may be removed. In one or more embodiments, the planarization process may be a chemical mechanical polishing process, but the disclosure is not limited thereto. The top surface of the interlayer insulating layer 104 located on top and the top surface of the external electrode 116 may be located on the same plane by the planarization process.

Next, the upper insulating layer 109 may be formed to cover the top surface of the interlayer insulating layer 104 located on top, the top surface of the external electrode 116, and the top surface of the lower insulating layer 107. The upper insulating layer 109 may include, for example, a silicon oxide.

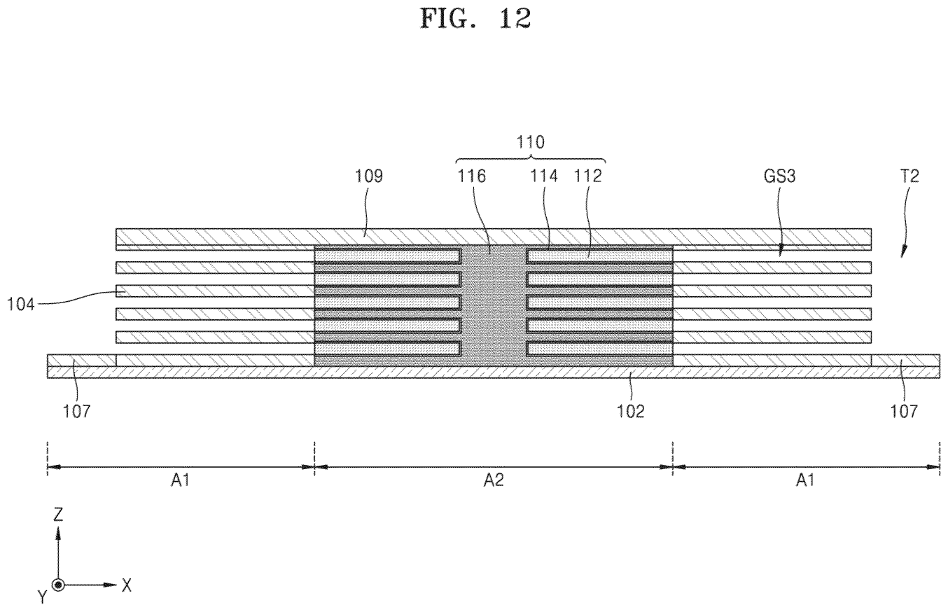

Referring to FIG. 12, in a resultant product of FIG. 11, a second trench T2 may be formed by removing a part of the lower insulating layer 107 and a part of the upper insulating layer 109, and a third space GS3 may be formed by removing the sacrificial layer 106 (see FIG. 11) in the first region A1 through the second trench T2. The second trench T2 and the third space GS3 may communicate with each other. The third space GS3 may be formed by performing a wet etching process. An end portion of the internal electrode 112 and surfaces of the interlayer insulating layer 104 may be exposed by the second trench T2 and the third space GS3.

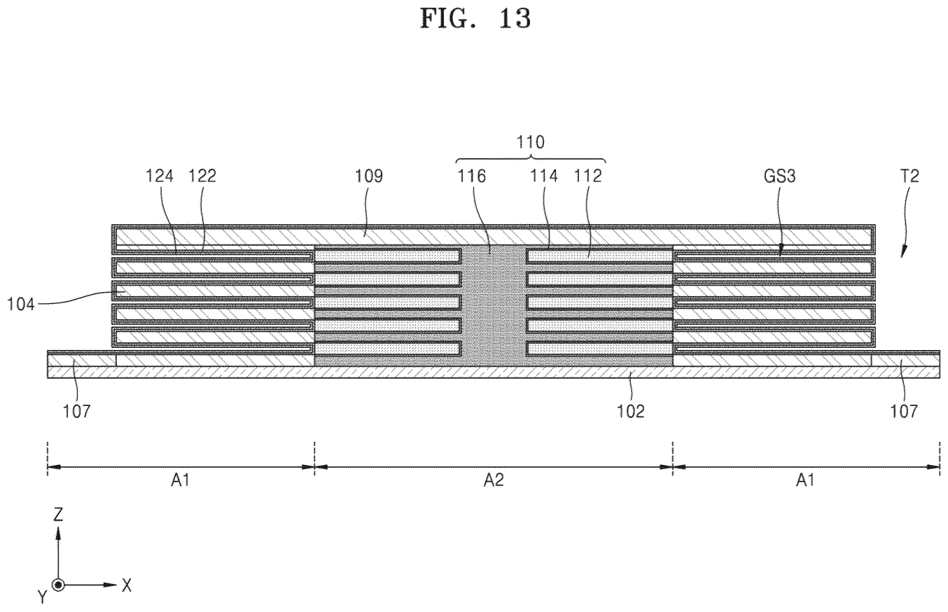

Referring to FIG. 13, in a resultant product of FIG. 12, the channel region 122 may be formed to cover an end portion of the internal electrode 112 exposed by the second trench T2 and the third space GS3, the surfaces of the interlayer insulating layer 104, the surfaces of the upper insulating layer 109, and the surfaces of the lower insulating layer 107. A material of the channel region 122 may be as described above in the description of the semiconductor device 100 shown in FIGS. 1 and 2.

Next, the gate insulating layer 124 surrounding the surface of the channel region 122 may be formed. A material of the gate insulating layer 124 may be as described above in the description of the semiconductor device 100 shown in FIGS. 1 and 2.

The channel region 122 and the gate insulating layer 124 may be formed, for example, by a deposition process.

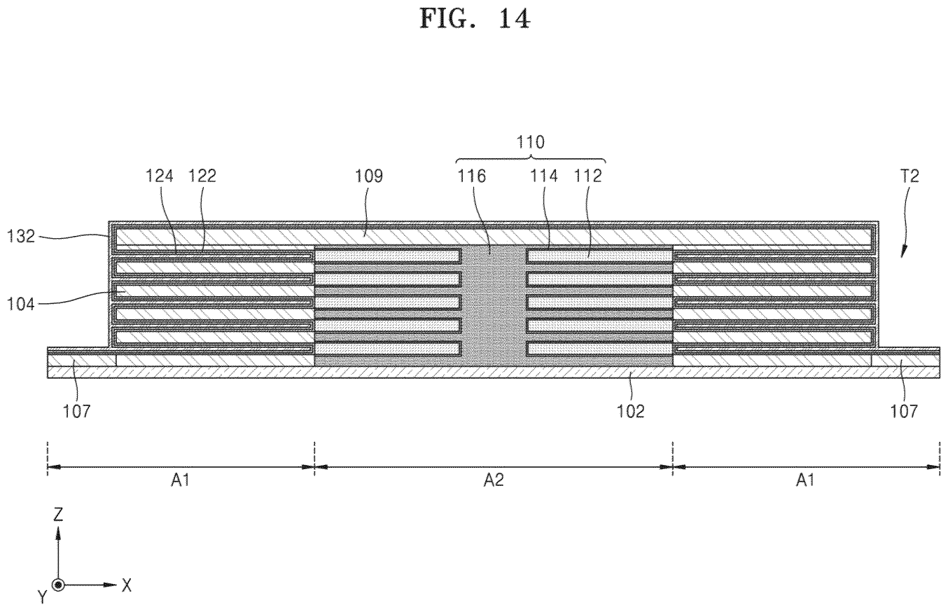

Referring to FIG. 14, in a resultant product of FIG. 13, the word line 132 surrounding the gate insulating layer 124 and filling the third space GS3 (see FIG. 13) may be formed. A material of the word line 132 may be as described above in the description of the semiconductor device 100 shown in FIGS. 1 and 2.

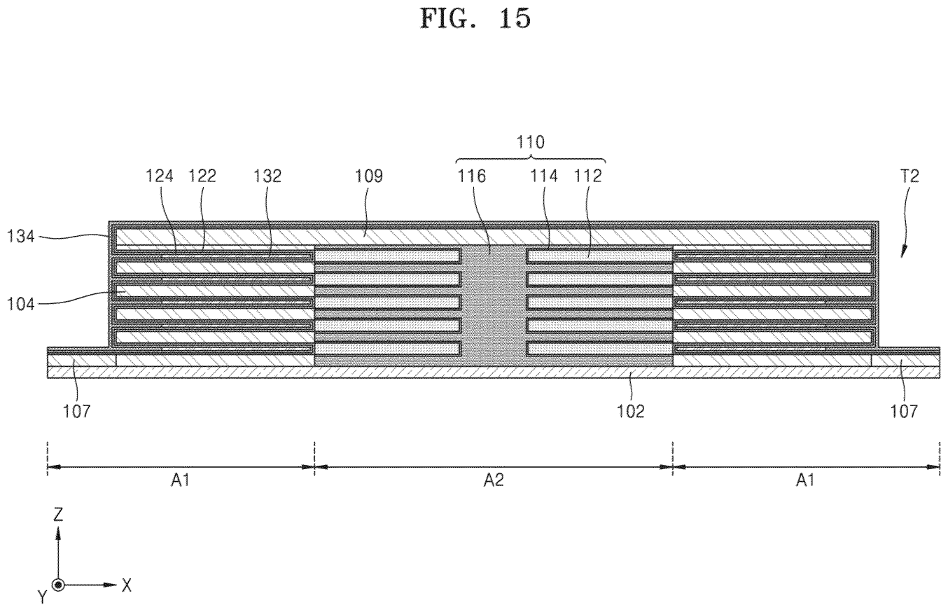

Referring to FIG. 15, in a resultant product of FIG. 14, the insulating pattern 134 may be formed in which a part of the word line 132 surrounding the gate insulating layer 124 is removed and a space having the removed part of the word line 132 is filled.

The part of the word line 132 may be removed, for example, by an etchback process. The insulating pattern 134 may be formed by, for example, a deposition process. A material of the insulating pattern 134 may be, for example, a silicon nitride.

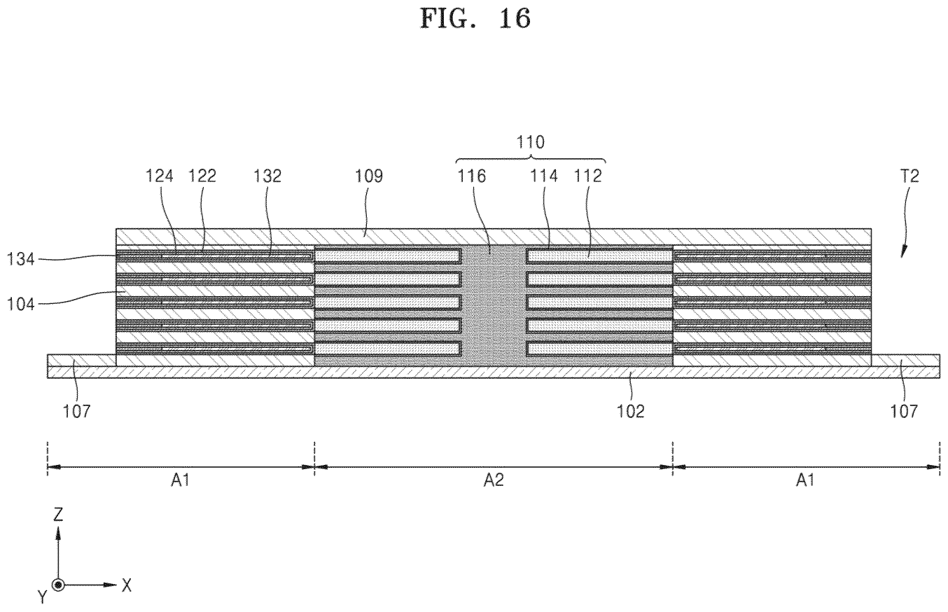

Referring to FIG. 16, in a resultant product of FIG. 15, a part of the insulating pattern 134 filling the third space GS3 (see FIG. 13), a part of the gate insulating layer 124, the other some part of the insulating pattern 134 than a part of the channel region 122, the other some part of the gate insulating layer 124, and the other some part of the channel region 122 may be removed. The surface of the lower insulating layer 107, side surfaces of the interlayer insulating layer 104, and the surface of the upper insulating layer 109 may be exposed by the process described with reference to FIG. 16. The part of the insulating pattern 134 may be removed, for example, by a strip process. A part of the gate insulating layer 124 and a part of the channel region 122 may be removed by, for example, a wet etching process.

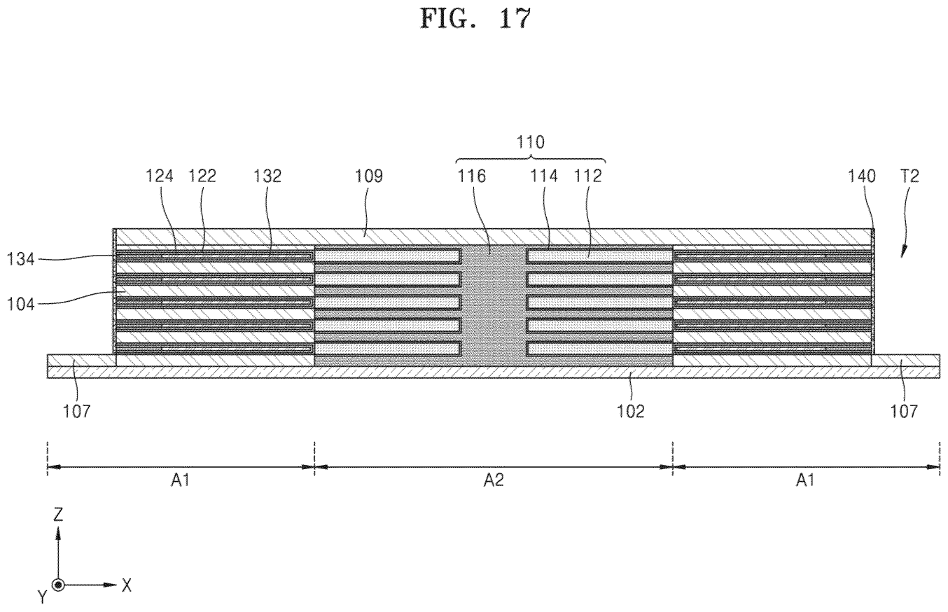

Referring to FIG. 17, in a resultant product of FIG. 16, the intermediate oxide layer 140 covering the side surfaces of the interlayer insulating layer 104 and the side surfaces of the upper insulating layer 109 may be formed. The intermediate oxide layer 140 may be formed by forming an oxide layer filling the second trench T2 and then removing a part of the oxide layer by using a mask pattern.

Next, in a resultant product of FIG. 17, by forming the bit line 150 filling the second trench T2, the semiconductor device 100 shown in FIGS. 1 and 2 may be formed.

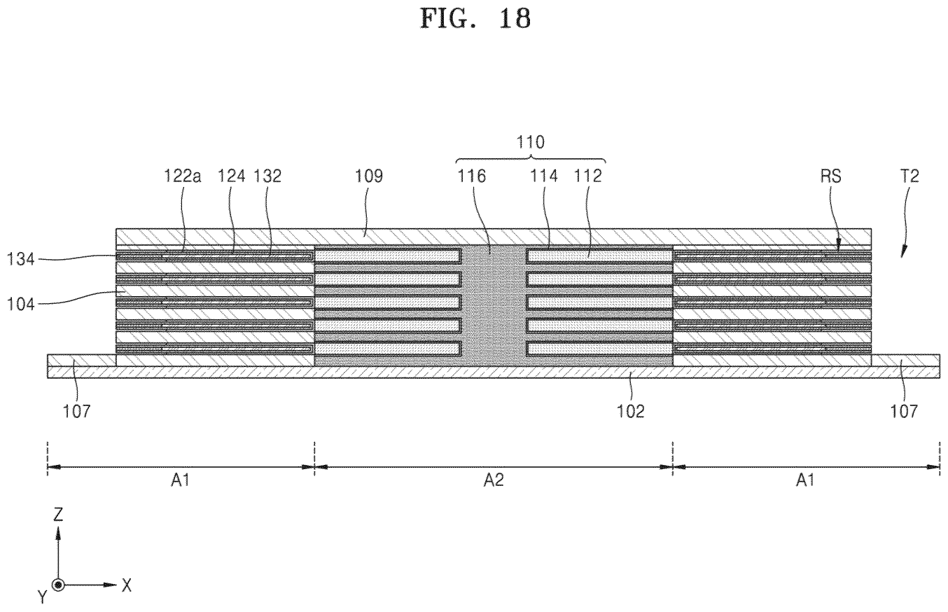

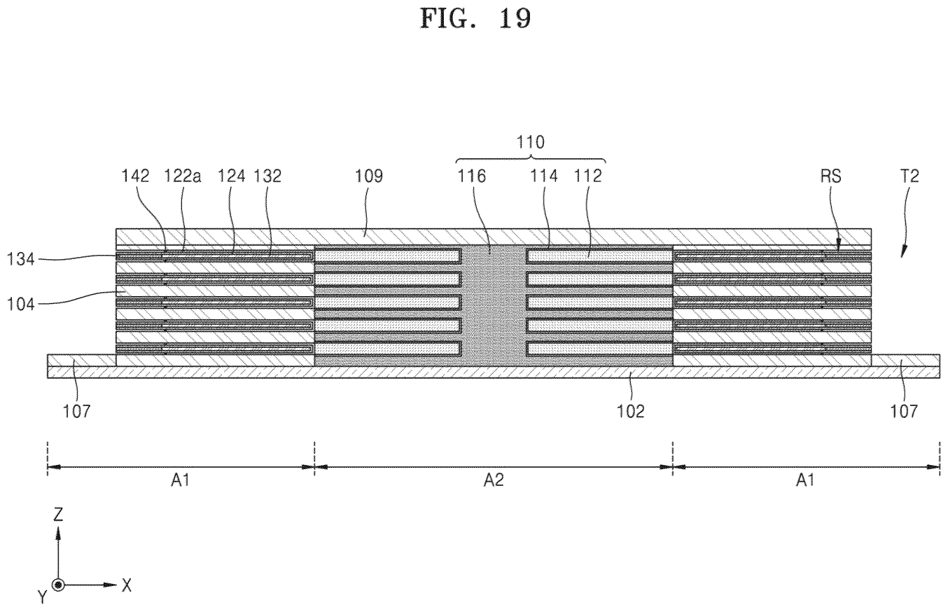

FIGS. 18 and 19 are cross-sectional views for describing a method of manufacturing the semiconductor device 100a according to one or more embodiments. Specifically, FIGS. 18 and 19 are cross-sectional views for describing a process performed to manufacture the semiconductor device 100a after the process shown in FIGS. 5 to 16 is performed.

Referring to FIG. 18, in a resultant product of FIG. 16, a part of the channel region 122 (see FIG. 16) may be removed to form a recess space RS. The recess space RS may further extend inward relative to the word line 132. That is, an outer sidewall of the word line 132 may be located outward relative to an outer sidewall of the channel region 122a exposed by the recess space RS. A channel region in which the part of the channel region 122 of FIG. 16 is removed may be defined as the channel region 122a.

Referring to FIG. 19, in a resultant product of FIG. 18, the intermediate oxide layer 142 filling a part of the recess space RS may be formed. The intermediate oxide layer 142 may cover a sidewall of the channel region 122a exposed by the recess space RS. In this case, the outer sidewall of the intermediate oxide layer 142 may be located inward relative to the outer sidewall of the word line 132. A material of the intermediate oxide layer 142 may be as described above in the description of the semiconductor device 100a shown in FIGS. 3 and 4.

Next, in a resultant product of FIG. 19, by forming the bit line 152 including the second portion 152E filling the recess space RS and the first portion 152C filling the second trench T2, the semiconductor device 100a shown in FIGS. 3 and 4 may be manufactured.

As above, embodiments have been disclosed in the drawings and specifications. Although the embodiments have been described using specific terms herein, they are merely used for the purpose of explaining the technical idea of the disclosure, and are not used to limit the scope of the disclosure described in the claims. It would be fully understood by those of ordinary skill in the art that various modifications and other equivalent embodiments are possible from the embodiments. Accordingly, the true technical scope of the disclosure should be defined by the technical spirit of the appended claims.

While the disclosure has been particularly shown and described with reference to embodiments thereof, it will be understood that various changes in form and details may be made therein without departing from the spirit and scope of the following claims.

What is claimed is:

1. A semiconductor device comprising:
a bit line extending in a vertical direction;
a word line extending in a horizontal direction;
a channel region around the word line;
a gate insulating layer between the word line and the channel region;
a capacitor comprising:
an internal electrode connected to the channel region;
a dielectric film around the internal electrode; and
an external electrode around the internal electrode with the dielectric film therebetween; and
an intermediate oxide layer between the bit line and the channel region.

2. The semiconductor device of claim 1, wherein the intermediate oxide layer extends in the vertical direction along a sidewall of the bit line.

3. The semiconductor device of claim 1, wherein a top surface of the intermediate oxide layer is on a same plane as a top surface of the bit line, and a bottom surface of the intermediate oxide layer is on a same plane as a bottom surface of the bit line.

4. The semiconductor device of claim 1, wherein a horizontal width of the intermediate oxide layer is 0.5 nm to 3 nm.

5. The semiconductor device of claim 1, wherein the intermediate oxide layer comprises Al₂O₃, TiO₂, ZnO, or a combination thereof.

6. The semiconductor device of claim 1, wherein a sidewall of the intermediate oxide layer contacts the bit line, and another sidewall of the intermediate oxide layer, opposite the sidewall of the intermediate oxide layer, contacts the channel region and the gate insulating layer.

7. The semiconductor device of claim 1, further comprising:
an insulating pattern between the word line and the intermediate oxide layer.

8. A semiconductor device comprising:
a bit line comprising a first portion extending in a vertical direction and a second portion protruding from the first portion in a first horizontal direction;
a word line extending in a second horizontal direction intersecting the first horizontal direction;
a channel region around at least a part of the word line;
a gate insulating layer between the word line and the channel region;
a capacitor comprising:
an internal electrode connected to the channel region;
a dielectric film around the internal electrode; and
an external electrode around the internal electrode with the dielectric film therebetween; and
an intermediate oxide layer between the second portion and the channel region.

9. The semiconductor device of claim 8, wherein the intermediate oxide layer overlaps the word line in the vertical direction.

10. The semiconductor device of claim 8, wherein a top surface of the intermediate oxide layer is on a same plane as a top surface of the second portion and a top surface of the channel region, and a bottom surface of the intermediate oxide layer is on a same plane as a bottom surface of the second portion and a bottom surface of the channel region.

11. The semiconductor device of claim 8, wherein the word line overlaps the channel region and at least a part of the second portion of the bit line in the vertical direction.

12. The semiconductor device of claim 8, further comprising:
an insulating pattern between the word line and the first portion of the bit line.

13. The semiconductor device of claim 12, wherein the insulating pattern overlaps the second portion of the bit line in the vertical direction.

14. The semiconductor device of claim 12, wherein the insulating pattern contacts the word line on a sidewall thereof and contacts the first portion on another sidewall thereof opposite the sidewall.

15. The semiconductor device of claim 8, wherein a horizontal width of the intermediate oxide layer is 0.5 nm to 3 nm.

16. The semiconductor device of claim 8, wherein the intermediate oxide layer comprises Al₂O₃, TiO₂, ZnO, or a combination thereof.

17. A semiconductor device comprising:
a bit line extending in a vertical direction;
interlayer insulating layers;
word lines alternately stacked with the interlayer insulating layers and extending in a horizontal direction;
insulating patterns between the word lines and the bit line;
channel regions around the insulating patterns and the word lines;
gate insulating layers between word lines and the channel regions and between the insulating patterns and the channel regions;
a capacitor comprising:
internal electrodes connected to the channel regions;
dielectric films around the internal electrodes; and
external electrodes around the internal electrodes with the dielectric films therebetween; and
an intermediate oxide layer between the bit line and the channel regions and extending in the vertical direction along a sidewall of the bit line.

18. The semiconductor device of claim 17, wherein the channel regions comprise an InGaZnO (IGZO) material.

19. The semiconductor device of claim 17, wherein a horizontal width of the intermediate oxide layer is 0.5 nm to 3 nm.

20. The semiconductor device of claim 17, wherein the intermediate oxide layer comprises Al₂O₃, TiO₂, ZnO, or a combination thereof.
